(19) United States
(12) Patent Application Publication
(10) Pub. No.: US 2007/0012931 A1
(43) Pub. Date: Jan. 18, 2007

(54) White semiconductor light emitting device

(75) Inventors: Dong-Yeoul Lee, Kimhae-city (KR); Yong-Tae Kim, Cheonju-city (KR); Sang-Ho Lee, Busan-city (KR); Jin-Hwan Kim, Iksan-city (KR); Min-Sang Lee, Daeku-city (KR)

Correspondence Address: CONLEY ROSE, P.C., P. O. BOX 3267, HOUSTON, TX, 77253-3267, US

(73) Assignee: LUXPIA CO., LTD., JEOLLABUK-DO (KR)

(21) Appl. No.: 10/554,469

(22) PCT Filed: Apr. 23, 2004
(86) PCT No.: PCT/KR04/00943

§ 371 Date: Oct. 25, 2005

(30) Foreign Application Priority Data
Apr. 25, 2003 (KR) 10-2003-0026351

(51) Int. Cl. H01L 33/00

(52) U.S. Cl. 257/89

(57) ABSTRACT

A white light semiconductor light emitting device includes a semiconductor LED and first and second phosphors provided on a light emitting region of the LED to emit light within a first wavelength range, which is different from that of light emitted from the LED, by absorbing a portion of the light emitted from the LED. The first and second phosphors are respectively a barium-silicate-base green phosphor and a zinc-selenium-base red phosphor.

### BACKGROUND OF THE INVENTION

a) Field of the Invention

The present invention relates to a white light semiconductor light emitting device, and more particularly, to a white light semiconductor light emitting device that can emit a white light by applying a barium-silicate-base phosphor emitting a green light and a zinc-selenium-base phosphor emitting a red light to a light transmitting layer deposited on a light emitting diode emitting a blue light, thereby emitting a white light by a color mixture of the red, green, and blue lights.

b) Description of the Related Art

A semiconductor light emitting diode (LED) is a junction diode of a P-type semiconductor and an N-type semiconductor. When a voltage is applied to the diode, the diode is designed to emit a light converted from energy, which corresponds to a band-gap of a semiconductor and is generated by an electron/hole bond.

In order to use the LED as a light, it should be designed to emit a white light As the LED is full colorized by the development of a light luminescent blue LED formed of a GaN-base nitride semiconductor, they are widely used. Particularly, the LEDs have been in the spotlight as lighting devices that are enduring, environmentally-friendly, and consume little power as compared with a fluorescent lamp and a glow lamp.

In recent years, white light emitting diodes have been widely used as a backlight for liquid crystal displays (LCD), as well as for general lighting devices. The white light emitting diode is realized by combine a YAG:Ce phosphor to a blue LED, or by a package composed of red, green, and blue LEDs. The white LED using the blue LED excites a YAG:Ce yellow phosphor deposited on an upper layer using blue light in a frequency range of 450-470 nm, thereby emitting white light formed by a light mixture of the blue and yellow colors. However, the phosphor material used for the white LED using the blue LED having the frequency range of 450-470 nm is limited to YAG:Ce, which has a color purity problem.

In order to make a white light semiconductor light emitting device using the red, green, and blue LEDs, a variety of substrates such as GaAS, ALGaInP, InGaN, and GaN should be separately prepared, utilizing different semiconductor layers. This causes the manufacturing costs to be increased, while complicating the manufacturing process. Therefore, there is a need for a white light semiconductor light emitting device that can emit white light using an identical semiconductor layer, and that can provide improved color purity.

An infrared LED may be used to realize white light by exciting a three-primary-color phosphor. At this point, InGaN/R,G,B is widely used as the light emitting material. The white light emitting method using the infrared LED has advantages in that it can be used under a high-current and it improves the color sense. However, since the development of a material for realizing the green color is not sufficient, and a short wavelength light emitted from the blue LED is absorbed into the long wavelength red LED, the overall light emitting efficiency is deteriorated.

A variety of well-known white light semiconductor light emitting devices are exemplified hereinafter.

U.S. Pat. Nos. 5,998,925 and 6,069,440, assigned to Nichia, disclose a light emitting device comprised of a blue LED having a nitride semiconductor represented by InᵢGaⱼAlₖN (0 I, 0 j, 0 k, I+J+k=1) and a YAG (Yttrium, Aluminum, Garnet)-base garnet phosphor for absorbing a part of the light emitted from the blue LED and emitting light having a wavelength different from that of the absorbed light.

U.S. Pat. No. 6,504,179, assigned to Osram, discloses a white light device employing a BYG approach (a combination of blue, yellow, and green colors), instead of using an RGB approach (a combination of red, green, and blue colors) or a BY approach (a combination of blue and yellow colors).

U.S. Pat. No. 6,596,195, assigned to General Electric, discloses a white light source having a phosphor that can be excited by light within a wavelength range from near ultraviolet light to a blue light wavelength range (approximately 315-480 nm), emitting a visible ray representing a luminous peak at a wavelength range (approximately 490-770 nm) of from green light to yellow light.

The above-described prior white light semiconductor light emitting devices are designed to emit white light by combination of colors generated by exciting YAG-base yellow phosphor using a UV or blue LED. However, the YAG-base yellow phosphor emits a yellow-green color light. Therefore, another material should be added to vary the yellow-green light wavelength into a long wavelength, deteriorating the luminescence and brightness.

The inventive white light semiconductor light emitting device has a blue LED having a light emitting chip with a permeable resin layer with which a silicate-base green phosphor and a selenium-base red phosphor are mixed, thereby emitting white light generated by a combination of blue light emitted from the blue LED, green light emitted from the silicate-base phosphor absorbing a portion of the blue light, and red light emitted from the selenium-base red phosphor absorbing a portion of the blue light

### BRIEF DESCRIPTION OF THE DRAWINGS

The accompanying drawings, which are included to provide a further understanding of the invention and are incorporated in and constitute a part of this application, illustrate embodiment(s) of the invention, and together with the description serve to explain the principles of the invention. In the drawings:

FIGS. 1a and 1b are respectively schematic and partly enlarged views of a lead-type white light semiconductor light emitting device utilizing a barium-silicate-base green phosphor and a zinc-selenium-base red phosphor according to the present invention;

FIGS. 2a and 2b are respectively schematic and partly enlarged views of a lead-type white light semiconductor light emitting device utilizing a barium-silicate-base green phosphor, a zinc-selenium-base red phosphor and a dual-mold according to the present invention;

FIG. 3 is a schematic view of a surface mounting type white light semiconductor light emitting device of a reflector injection structure type, which utilizes a barium-silicate-base green phosphor and a zinc-selenium-base red phosphor, according to the present invention;

FIG. 4 is a schematic view of a surface mounting type white light semiconductor light emitting device of a reflector injection structure type, which utilizes a barium-silicate-base green phosphor, a zinc-selenium-base red phosphor, and a dual mold, according to the present invention;

FIG. 5 is a schematic view of a surface mounting type white light semiconductor light emitting device of a PCB type, which utilizes a barium-silicate-base green phosphor and a zinc-selenium-base red phosphor, according to the present invention;

FIGS. 6a and 6b are graphs respectively showing light absorption and light emitting spectrums of a barium-silicate-base green phosphor and a zinc-selenium-base red phosphor according to the present invention;

FIG. 7 is a graph illustrating an light emitting spectrum of a white LED that is formed by a combination of a barium-silicate-base green phosphor, a zinc-selenium-base red phosphor, and a blue LED according to the present invention; and

FIG. 8 is a color coordinate chart illustrating a color reproduction range that can be realized by a semiconductor light emitting device formed by a combination of a barium-silicate-base green phosphor, a zinc-selenium-base red phosphor, and a blue LED.

### DETAILED DESCRIPTION OF THE INVENTION

It is an objective of the present invention to provide to a white light semiconductor light emitting device that can emit a white light by applying a barium-silicate-base phosphor emitting a green light and a zinc-selenium-base phosphor emitting a red light to a light transmitting layer deposited on a light emitting diode emitting a blue light, thereby emitting a white light by a color mixture of the red, green, and blue lights.

To achieve the objective, the present invention provides a white light semiconductor light emitting device that comprises:

a blue or ultraviolet LED connected to anode and cathode terminals to emit light when current is applied thereto;

a zinc-selenium-base red phosphor provided on a light emitting region of the LED to emit red light by absorbing the light emitted from the LED; and

a barium-silicate-base green phosphor provided on a light emitting region of the LED to emit green light by absorbing the light emitted from the LED,

wherein the zinc-selenium-base red phosphor and the barium-silicate-base green phosphor is provided in or on an epoxy mold layer enclosing at least one surface of the LED.

The epoxy mold layer can be applied to a lead-type device provided with a reflecting dam formed in a cup-shape or a plate-shape, or as a surface mounting type of device, thereby protecting the LED from physical impact.

When the epoxy mold layer is applied to the lead-type device, the epoxy mold layer containing the barium-silicate-base green phosphor and the zinc-selenium-base red phosphor is deposited on a top surface of the LED while being filled in a hole cup.

When the epoxy mold layer is applied to the surface mounting type of device, a permeable resin mold layer containing the barium-silicate-base green phosphor and the zinc-selenium-base red phosphor is deposited on a top surface of the LED while being filled in a frame.

At this point, the LED is formed of a GaN, InGaN, or AlGaInN-base blue LED chip with a sapphire substrate, or a GaN, InGaN, or AlGaInN-base blue LED chip with a silicon carbide (SiC) substrate.

Alternatively, a GaN, InGaN, or AlGaInN-base blue LED chip with another predetermined substrate may be used.

The phosphors suitable for the inventive white light semiconductor light emitting device is Green and red light emitting phosphors that can be excited by ultraviolet light emitted from a semiconductor light emitting layer, or by light energy in a visible ray range.

The barium-silicate-base green light emitting phosphor is represented by the following chemical formula 1,
(Ba_{1-P}X_{P})₂SiO₄:Y (Chemical Formula I)

where X is more than one chemical element selected from the group consisting of Sr, Ca, Mg, K, and Na; and Y is more than one chemical element selected from the group consisting of Eu, Tb, Mn, Y, Gd, Ho, Ce, Er, Tm, La, Sm, and Dy.

The zinc-selenium-base red light emitting phosphor is represented by the following chemical formula 2,
(Zn₁₋ₐX_{q})₂SeO₄:Y (Chemical Formula 2)

where X is more than one chemical element selected from the group consisting of Cd, Ca, Mg, Li, Ba, and Sr; and Y is more than one chemical element selected from the group consisting of an IB group (Cu and Ag), a IIIB group (Al, Ga, and In), and a VIIB group (Cl, Br, and I), or rare-earth-elements (Eu, Ce, Pr, Dy, and Sm).

The barium-silicate-base green light emitting phosphor and the zinc-selenium-base red light emitting phosphor will be described more in detail hereinafter.

The barium-silicate-base green light emitting phosphor is represented by the chemical formula (Ba_{1-P}X_{P})₂SiO₄:Y. X is more than one chemical element selected from the group consisting of Sr, Ca, Mg, K, and Na, at a rate of 0-1 mol. Y is more than one chemical element selected from the group consisting of Eu, Th, Mn, Y, Gd, Ho, Ce, Er, Tm, La, Sm, and Dy, at a rate of 0-0.5 mol.

The zinc-selenium-base red light emitting phosphor is represented by the chemical formula (Zn_{1-q}X_{q})₂SeO₄:Y. X is more than one chemical element selected from the group consisting of Cd, Ca, Mg, Li, Ba, and Sr, preferably at a rate of 0-0.1 mol. Y is more than one chemical element selected from the group consisting of an IB group (Cu and Ag), a IIIB group (Al, Ga, and In), and a VIIB group (Cl, Br, and I), or rare-earth-elements (Eu, Ce, Pr, Dy, and Sm), at a rate of 0-1 mol. When a rate of the co-activator in the barium-silicate-base green light emitting phosphor and the zinc-selenium-base red light emitting phosphor is lower than the above-described range, it cannot function as the co-activator, and when higher than the range, the brightness is deteriorated due to a concentration-quenching effect.

Each of the green and red phosphors is manufactured according to the following process.

A phosphor material and co-activator are mixed at a predetermined rate. At this point, in order for the materials to be more uniformly mixed, the materials are mixed under an acetone solvent by a mixing machine such as a ball mill. The mixture is dried at a temperature of about 100° C.-150° C. for 1-2 hours. The dried mixture is heat-treated at a temperature of about 800° C.-1500° C. to a compound phosphor powder. The compounded phosphor powder is baked under a reduction atmosphere at a temperature of about 800° C.-1500° C. for 1-10 hours and is then ground. Photoluminescence of the powder was measured. According to the results, it was noted that the barium-silicate-base green phosphor appears as an intensive luminous spectrum in a range of 450-800 nm, and the zinc-selenium-base red phosphor appears as an intensive luminous spectrum in a range of 500-700 nm.

In the course of making the inventive white light semiconductor light emitting device, the green and red light emitting phosphors are deposited on the top surface of the LED chip while being filled in the hole cup or the frame. The phosphors are actually provided on the permeable resin mold layer located on the LED chip. The zinc-selenium-base red phosphor and the barium-silicate-base green phosphor contained in the permeable resin mold are multi-layered in a large particle layer, a medium particle layer, and a small particle layer from a bottom of the hole cup or the groove of the frame. Preferably, the phosphors are filled in the resin mold layer by precipitation and hardened, after which the mold material is solidified. When the mold material is solidified in a state where the phosphors are densely precipitated in the resin mold layer, the light emitted from the LED is absorbed by the phosphor particles and scattered, thereby improving the intensity and uniformity of the white light.

However, when the mold material is solidified in a state where the phosphors are not densely precipitated in the resin mold layer and hardened, the light emitted from the LED is absorbed by the floated phosphor particles near the surface of the LED chip and is then emitted as secondary light. However, the secondary light collides with phosphor particles remote from the surface of the LED chip, therefore not contributing to the light emission. That is, a portion of the secondary light transmits and another portion of the secondary light is reflected and diffused, and another portion disappears, thereby deteriorating the luminous intensity. In addition, a size of each particle in the large and medium particle layers is preferably in a range of 2-50 μm, and a size of each particle in the small particle layer is preferably in a range of 0.1-2 μm. Since the light is emitted from a surface of each particle, as the size of the particle is reduced, the total surface area of the phosphor defined by the surface areas of the particles is increased, thereby enhancing the luminous intensity. However, when the size of the particle is smaller than a critical size, the scattered light is absorbed between the particles, deteriorating the luminous intensity. Furthermore, since the particles are insufficiently precipitated in the resin mold layer, the mold material is solidified in a state where the particles float, thereby further deteriorating the luminous intensity. That is, the large and medium size particles are first filled from the bottom of the hole cup or the frame, and the small size particles each having a size of 0.1-2 μm are filled on the large and medium size particles in the cup or the frame. Particularly, the large size particles are disposed not to overlap around the LED chip to emit uniform white light while increasing the luminous intensity.

As described above, the LED is designed having a high energy band gap, emitting white light formed by the combination of the blue light emitted from a nitride-gallium compound-base semiconductor device, the green phosphor emitted from the barium-silicate-base green phosphor, and the red light emitted from the zinc-selenium-base red phosphor.

In addition, in the white LED having the barium-silicate-base green phosphor and the zinc-selenium-base red phosphor, even when high energy light in a visible light wavelength range is irradiated for a long time, the color variation of the emitted light or the deterioration of the brightness are incurred.

Reference will now be made in detail to the preferred embodiments of the present invention.

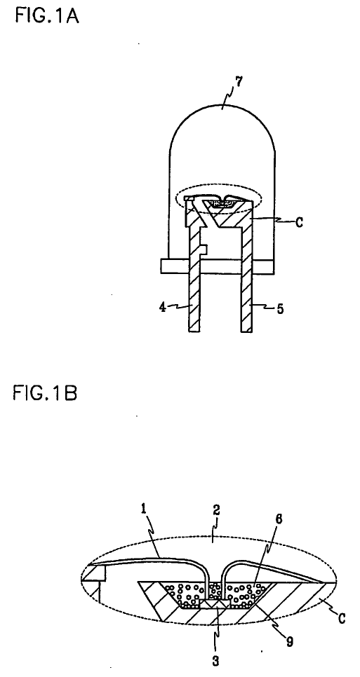

FIGS. 1a and 1b are respectively schematic and partly enlarged views of a lead-type white light semiconductor light emitting device utilizing a barium-silicate-base green phosphor and a zinc-selenium-base red phosphor according to the present invention. As shown in the drawings, a lead-type white LED as is well known in the art is used, having a cup-shaped reflection plate. However, another LED having a similar structure to the lead-type LED can be also employed. An LED chip 3 is connected to an anode lead 4 and a cathode lead 5 by an anode wire 1 and a cathode wire 2, respectively. A hole cup C functioning as a reflector is integrally formed on an end of the cathode lead 5. The LED chip 3 is located in the hole cup C. The LED chip 3 may be formed of a blue LED chip.

The LED chip 3 and portions of the anode and cathode wires 1 and 2 are enclosed by an epoxy mold layer 6. That is, the LED chip 3 is protected by the epoxy mold layer from external impact. Two phosphors relating to the present invention are mixed with the epoxy mold layer.

Therefore, the epoxy mold layer 6 is formed in the hole cup C, and a wrapping material 7 such as a colorless or colored permeable resin is molded around the hole cup C and the mold layer 6.

As a feature of the present invention, a barium-silicate-base green phosphor and a zinc-selenium-base red phosphor are provided in the epoxy mold layer 6 to correspond to a light emitting path of the blue LED.

In the present invention, the barium-silicate-base green phosphor and the zinc-selenium-base red phosphor are mixed with the epoxy resin such that they can be randomly distributed in the epoxy mold layer 6 or such that they can alternately arranged in a matrix pattern.

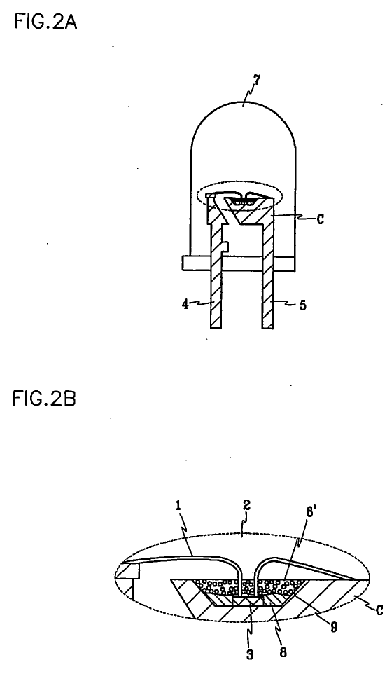

FIGS. 2a and 2b are respectively schematic and partly enlarged views of a lead-type white light semiconductor light emitting device utilizing a barium-silicate-base green phosphor, a zinc-selenium-base red phosphor, and a dual-mold according to another embodiment of the present invention. This embodiment is different from the forgoing embodiment depicted in FIG. 1 in that the mold material is formed in a dual-layer in the hole cup C. That is, a silicone layer or a mold layer is formed around the LED chip 3 in the hold cup C. Considering a depth of the hole cup C is about 0.25-0.55 mm and a height of the blue LED chip 3 is about 100 μm, it is preferable that a thickness of the silicone layer or the mold layer 8 is about 100-200 μm. The epoxy mold layer 6 containing the barium-silicate-base green phosphor and the zinc-selenium-base red phosphor is formed on the silicon or mold layer 8 while covering an upper portion of the hole cup C.

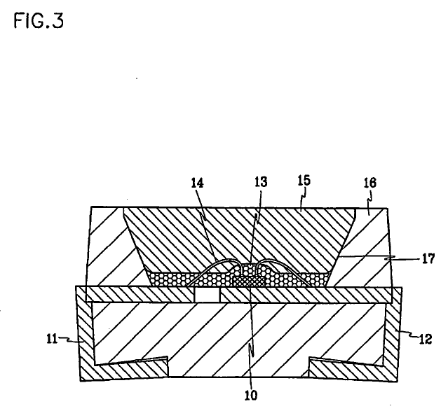

FIG. 3 is a schematic view of a surface mounting type white light semiconductor light emitting device of a reflector injection structure type, which utilizes a barium-silicate-base green phosphor and a zinc-selenium-base red phosphor, according to another embodiment of the present invention. As shown in the drawing, an LED of this embodiment comprises a blue LED chip 10, an anode lead 11, a cathode lead 12, an epoxy mold layer 13, and a cup-shaped reflector 16 formed of an opaque resin. The reflector 16 is provided at its inner circumference with a reflecting surface 17. The anode and cathode lead 11 and 12 are formed of fine metal wires 14, being respectively connected to N-type and P-type electrodes of the LED chip 10. The epoxy mold layer 13 contains the barium-silicate-base green phosphor and the zinc-selenium-base red phosphor. The epoxy mold layer 13 is formed on the bottom of the cup C while covering a top surface of the LED chip 10. The transparent silicone or mold layer 15 is formed on the epoxy mold 13, having an identical plane to that of the reflector 16. As the blue LED chip, a UV chip may be used.

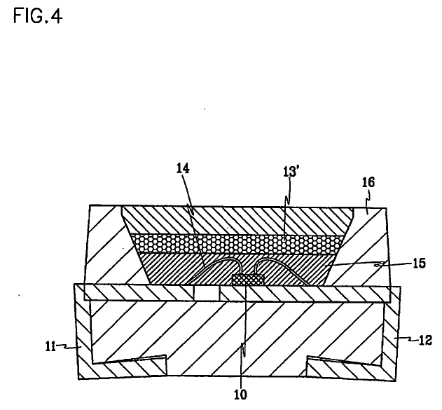

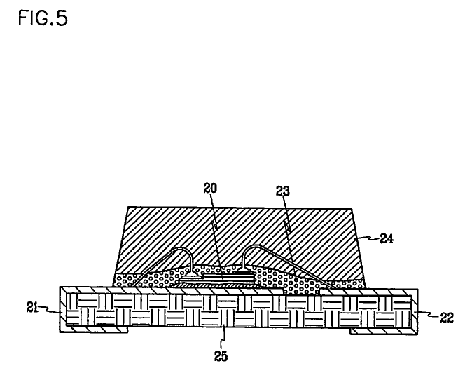

FIG. 4 is a schematic view of a surface mounting type white light semiconductor light emitting device of a reflector injection structure type, which utilizes a barium-silicate-base green phosphor, a zinc-selenium-base red phosphor, and a dual mold, according to another embodiment of the present invention.

An LED of this embodiment has a triple mold layer. That is, a transparent silicone or mold layer 15 is formed on a bottom of the cut while covering a top surface of the LED chip 10. An epoxy mold layer 13′ containing a barium-silicate-base green phosphor and a zinc-selenium-base red phosphor is formed on the transparent silicone or mold layer 15, and another transparent silicone or mold layer is formed on the epoxy mold layer 13′, having a plane identical to a top of the cup C. Likewise, a photo-density of the epoxy mold layer 13′ can be improved by precipitating the phosphors using a specific gravity difference between the phosphors and the mold material.

FIG. 5 is a schematic view of a surface mounting type white light semiconductor light emitting device of a PCB type, which utilizes a barium-silicate-base green phosphor and a zinc-selenium-base red phosphor, according to another embodiment of the present invention. A white light semiconductor light emitting device of this embodiment comprises an LED chip 20, an anode lead 22, a cathode lead 21, and an epoxy resin layer 23 containing phosphors. The LED chip 20 is located on a PCB 25, having N-type and P-type electrodes connected to the leads 21 and 22, respectively. The phosphors contained in the epoxy mold layer 23 include a barium-silicate-base green phosphor and a zinc-selenium-base red phosphor. The epoxy mold layer 23 is formed covering the LED chip 20. A transparent silicone layer or mold layer 24 is formed on the epoxy mold layer 23.

The LED chip 20 may be formed of a blue LED chip or a UV LED chip. The multiple-layer structure of the above-described embodiments can be variably modified.

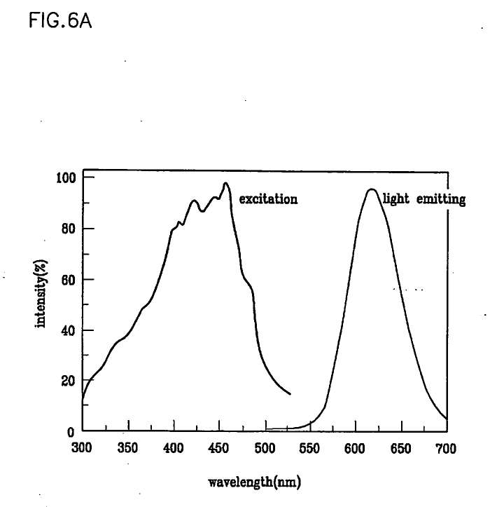

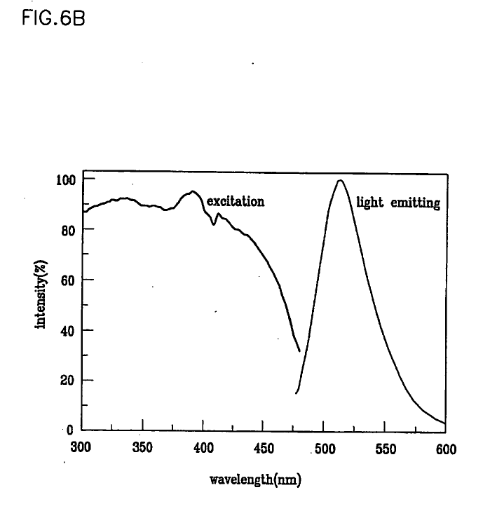

FIGS. 6a and 6b are graphs respectively showing light absorption and light emitting spectrums of a barium-silicate-base green phosphor and a zinc-selenium-base red phosphor according to the present invention. Referring first to FIG. 6a, there is shown light absorption and light emitting spectrums of a zinc-selenium-base red phosphor. This phosphor has a high absorption peak at a wavelength of 400-450 nm and an intensive light emitting peak at a wavelength of 600-650 nm.

Referring first to FIG. 6b, there is shown light absorption and light emitting spectrums of a barium-silicate-base green phosphor. This phosphor has a high absorption peak at a wavelength of 300-420 nm, and an intensive light emitting peak at a wavelength of 500-550 nm.

The spectrums show that the LED using the UV or blue LED chip excites the phosphors by light energy at a wavelength band from the chip, thereby emitting the white light. This shows that the barium-silicate-base green phosphor and the zinc-selenium-base red phosphor are appropriate phosphors in the application having an energy source in the wavelength band.

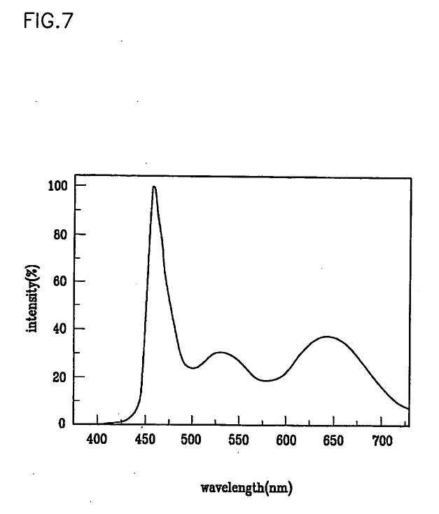

FIG. 7 is a graph illustrating a light emitting spectrum of a white LED that is formed by a combination of a barium-silicate-base green phosphor, a zinc-selenium-base red phosphor, and a blue LED according to the present invention. As shown in the graph, a part of the reference light generated from the blue LED chip is absorbed by the phosphors. The reference light emitted from the blue LED, and the green and red lights emitted by the phosphors absorbing the reference light are mixed to realize the white light. Accordingly, the white light semiconductor light emitting device of the present invention is more appropriate for the backlight of a LCD as compared with a device emitting white light by combining blue light generated from the blue chip and yellow light emitted from the YAG:Ce yellow light emitting phosphor.

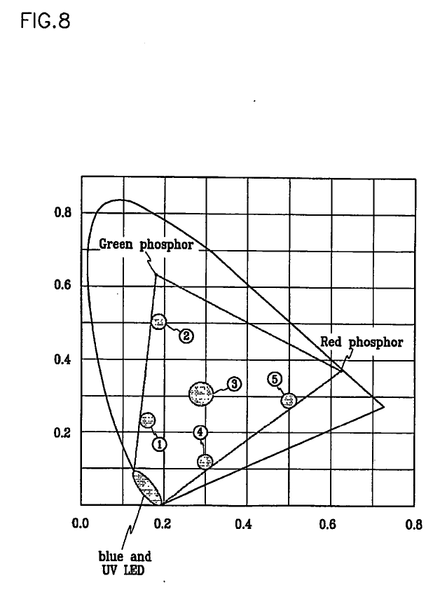

FIG. 8 is a color coordinate chart illustrating a color reproduction range that can be realized by a semiconductor light emitting device formed by a combination of a barium-silicate-base green phosphor, a zinc-selenium-base red phosphor, and a blue LED. As shown in the drawing, by adjusting an amount of a barium-silicate-base green phosphor and a zinc-selenium-base red phosphor that are applied to the blue chip, a range defined in the color coordinate chart can be realized.

In FIG. 8, a region \textcircled{1} (greenish blue color) and a region \textcircled{2} (green color) can be realized by varying W % of the green phosphor contained in the permeable mold resin layer used for the coating part. That is, the region \textcircled{1} can be realized by mixing 10 W % of the green phosphor with respect to the permeable mold resin. The region \textcircled{2} can be realized by mixing 60 W % of the green phosphor with respect to the permeable mold resin.

A region \textcircled{4} (purple color) and a region \textcircled{5} (pink color) can be realized by varying W % of the red phosphor contained in the permeable mold resin layer used for the coating part. That is, the region \textcircled{4} can be realized by mixing 5 W % of the red phosphor with respect to the permeable mold resin. The region \textcircled{5} can be realized by mixing 10 W % of the red phosphor with respect to the permeable mold resin.

A region \textcircled{3} is a white color region, having 25-35 W % of the green phosphor with respect to the permeable mold resin and 2-5 W % of the red phosphor, thereby realizing the white color.

The selective regions depicted in FIG. 8 show that a predetermined color within the solid line can be emitted by adjusting W % of the barium-silicate-base green phosphor and the zinc-selenium-base red phosphor in the permeable mold resin.

As described above, since the LED having the barium-silicate-base green phosphor and the zinc-selenium-base red phosphor emits very high quality green and red light by being excited by the light in a UV wavelength range and a blue wavelength range, it can be applied to a white light semiconductor light emitting device having green and red phosphors and a UV LED (reference light) or to a white light semiconductor light emitting device having green and pink phosphor and a blue LED (reference light), or to a variety of applications having energy source UV or blue wavelength ranges. Particularly, by applying green and red phosphors to a single blue LED chip, the white light is realized, thereby providing high quality color purity as compared with a prior semiconductor light emitting device having red, green, and blue LED chips, while reducing the manufacturing costs simply and simplifying manufacturing processes.

It will be apparent to those skilled in the art that various modifications and variations can be made in the present invention. Thus, it is intended that the present invention covers the modifications and variations of this invention provided they come within the scope of the appended claims and their equivalents.

1-15. (canceled)

16. A white light semiconductor light emitting device comprising:
a semiconductor LED; and
first and second phosphors provided on a light emitting region of the LED to emit light within a first wavelength range, which is different from that of light emitted from the LED, by absorbing a portion of the light emitted from the LED,
wherein the first and second phosphors are respectively a barium-silicate-base green phosphor and a zinc-selenium-base red phosphor.

17. The white light semiconductor light emitting device of claim 16, wherein the LED is formed of a GaN, InGaN, AlGaN, or AlGaInN-base blue LED chip.

18. The white light semiconductor light emitting device of claim 16, wherein the LED is disposed in a hole cup or a reflector for reflecting light emitted from the LED and is molded by epoxy resin containing phosphors.

19. The white light semiconductor light emitting device of any one of claims 18, wherein the first and second phosphors are randomly mixed or mixed in a matrix pattern.

20. The white light semiconductor light emitting device of claim 18, wherein the first and second phosphors are mixed with the epoxy mold resin.

21. The white light semiconductor light emitting device of any one of claims 20, wherein the first and second phosphors are randomly mixed or mixed in a matrix pattern.

22. The white light semiconductor light emitting device of any one of claims 16, wherein the first and second phosphors are randomly mixed or mixed in a matrix pattern.

23. The white light semiconductor light emitting device of claim 16, wherein the phosphor is formed of spherical particles or flake-like particles, a size of each particle being 0.1-50 μm

24. The white light semiconductor light emitting device of claim 16, wherein particles of the first and second phosphors are filled in a hole cup or a reflector in the order of large, medium, and small sizes.

25. The white light semiconductor light emitting device of claim 16, wherein the LED further comprises a transparent silicone layer or a transparent mold layer to reduce a light path length difference.

26. A white light semiconductor light emitting device comprising:
anode and cathode leads;
a hole cup formed on an end of one of the anode and cathodes leads;
an LED disposed in the hole cup and electrically connected to the anode and cathode leads;
an epoxy mold for molding the LED in the hole cup; and
a barium-silicate-base green phosphor and a zinc-selenium-base red phosphor that are mixed with the epoxy mold to emit light within a first wavelength range, which is different from that of light emitted from the LED, by absorbing a portion of the light emitted from the LED.

27. The white light semiconductor light emitting device of claim 16, which is a surface mounting device that is one of lead and reflector types.

28. The white light semiconductor light emitting device of claim 16, wherein the LED has a substrate formed of sapphire or silicon carbide.

29. The white light semiconductor light emitting device of claim 16, wherein the LED is formed of a GaN, InGaN, AlGaN, or AlGaInN-base UV LED chip.

30. A white light semiconductor light emitting device comprising:
an LED;
anode and cathode leads electrically connected to the LED;
a reflector in which the LED is disposed;
an epoxy layer for molding the LED in the reflector, being mixed with phosphors; and
a transparent silicone layer or a transparent mold layer disposed on the epoxy layer.

31. A white light semiconductor light emitting device comprising:
an LED;
anode and cathode leads electrically connected to the LED;
a reflector in which the LED is disposed;
a transparent silicone layer or a transparent mold layer for molding the LED in the reflector;
an epoxy layer mixed with phosphors and disposed on the transparent silicon layer or the transparent mold layer.

32. A white light semiconductor light emitting device comprising:
a PCB;
an LED disposed on the PCB;
a permeable epoxy resin mixed with a barium-silicate-base green phosphor and a zinc-selenium-base red phosphor, the permeable epoxy resin being provided to mold the LED on the PCB; and
a transparent silicone layer or a transparent mold layer disposed on the epoxy layer.

33. The white light semiconductor light emitting device of claim 16, wherein the phosphors include a green light emitting phosphor that has a chemical formula (Ba1-PXP)2SiO4:Y where X has at least one chemical element selected from the group consisting of Sr, Ca, Mg, K, and Na and a red light emitting phosphor that has a chemical formula (Zn1-qX′q)2SeO4:Y′ where X′ has at least one chemical element selected from the group consisting of Cd, Ca, Mg, Li, Ba, and Sr.
